(19) United States
(12) Patent Application Publication
(10) Pub. No.: US 2002/0124960 A1
(43) Pub. Date: Sep. 12, 2002

(54) Substrate processing apparatus

(75) Inventors: Takanobu Nakashima, Tokyo (JP); Tatsuhisa Matsunaga, Tokyo (JP)

Correspondence Address: BACON & THOMAS, PLLC, 625 SLATERS LANE, FOURTH FLOOR, ALEXANDRIA, VA, 22314

(73) Assignee: Hitachi Kokusai Electric Inc., Tokyo (JP)

(21) Appl. No.: 10/083,371

(22) Filed: Feb. 27, 2002

(30) Foreign Application Priority Data
Mar. 6, 2001 (JP) 2001-061167

(51) Int. Cl. C23F 1/00; C23C 16/00

(52) U.S. Cl. 156/345.31; 118/719

(57) ABSTRACT

A substrate processing apparatus includes an opener including a closure, the opener for opening and restoring a cap of a wafer carrier, wherein the closure has three or more suction elements for holding the cap of the wafer carrier. More than two lines are required to connecting all the suction elements and a center of a largest polygon formed by lines connecting the suction elements substantially coincides with a center of the cap.

### FIELD OF THE INVENTION

The present invention relates to a substrate processing apparatus; and, more particularly, to a device for opening and restoring a cap of a substrate carrier, e.g., for use in a substrate processing apparatus such as a batch-type vertical apparatus for performing a diffusion or a CVD (chemical vapor deposition) process to form a diffusion, an insulating or a metallic layer of integrated circuits on semiconductor wafers.

### BACKGROUND OF THE INVENTION

In a substrate processing apparatus such as a batch-type vertical apparatus for performing a diffusion or a CVD process (referred to as batch-type CVD apparatus hereinafter), semiconductor wafers are loaded into and unloaded from the apparatus while being kept in carriers. Two kinds of carriers have been conventionally used. One is a box-shaped cassette having a pair of openings on two opposite sides thereof and the other is a box-shaped FOUP (front opening unified pod; hereinafter, “pod”) having an opening on one side thereof with a cap removably mounted thereon.

In case of using the pod as a wafer carrier, the wafers can be kept protected from contaminations of ambient atmosphere while being transferred since the pod containing the wafers is airtightly closed. Accordingly, the degree of cleanliness required for a clean room equipped with the batch-type CVD apparatus may be lowered, which in turn reduces cost for the maintenance of the clean room. For such reasons, the pod has been gaining popularity as a carrier used in the batch-type CVD apparatus recently.

The batch-type CVD apparatus using the pod as a wafer carrier is provided with a pod opener capable of loading and unloading wafers into and from the pod therein while maintaining the cleanliness of the wafers in the pod and the housing of the apparatus. One example of such a conventional pod opener is disclosed in U.S. Pat. No. 5,772,386, wherein the pod opener is provided with a closure removably disposed on a wafer loading port. The closure has a pair of suction elements holding a cap of the pod located on the wafer loading port, a pair of supporting pins respectively disposed at the center of the corresponding suction elements and for being respectively inserted into corresponding aligning holes formed on the cap and a pair of keys for locking or unlocking the cap.

However, the conventional pod opener described above suffers from some drawbacks. First when the pair of pins are inserted in the alignment holes, the cap may not be firmly held by the closure due to certain clearance between the aligning holes and the pins. Further, since only a pair of suction elements are provided on the closure, the cap may not be held uprightly by the closure but rather tends to slant about the line connecting the two suction elements during a pod door opening and a restoring process. When the pod opener transferring the cap during opening or restoring the cap, in such case, the cap may collide with or come into contact with an unwanted object during the cap opening or the restoring process, which may result in the generation of undesired particulates or foreign substances in the system. More seriously, the cap may be stuck in a position rendering it impossible to restore or lock the cap properly on the pod.

### SUMMARY OF THE INVENTION

It is, therefore, a primary object of the present invention to provide a substrate processing apparatus incorporating a cap opener capable of holding a cap of a wafer carrier stably and firmly during a cap opening and restoring process.

In accordance with the present invention, there is provided a substrate processing apparatus, comprising:

an opener including a closure, the opener for opening and restoring a cap of a pod, wherein the closure has three or more suction elements for holding the cap of the pod.

### BRIEF DESCRIPTION OF THE DRAWINGS

The above and other objects and features of the present invention will become apparent from the following description of preferred embodiments given in conjunction with the accompanying drawings, in which:

FIG. 1 shows a schematic perspective view of a batch-type CVD apparatus in accordance with the present invention;

FIG. 2 illustrates a front perspective view of a pod opener;

FIG. 3 is a perspective view of the pod opener with pods disposed on the wafer loading ports;

FIG. 4 describes a rear schematic perspective view of the pod opener with some parts eliminated;

FIG. 5 represents a perspective view of the eliminated parts V in FIG. 4;

FIG. 6A shows a top view of a mechanism for mapping with the arm retracted;

FIG. 6B sets forth a top view of a mechanism for mapping with the arm in an operation position;

FIG. 7 offers a perspective view of a cover enveloping a rear portion of the pod opener;

FIGS. 8A and 8B respectively present a top and a side view of the terminal unit;

FIG. 9A depicts a closure having three suction elements in accordance with the third preferred embodiment; and

FIG. 9B provides a closure having 5 suction elements in accordance with the third preferred embodiments.

### DETAILED DESCRIPTION OF THE PREFERRED EMBODIMENTS

Preferred embodiments of the present invention will now be described with reference to the accompanying drawings.

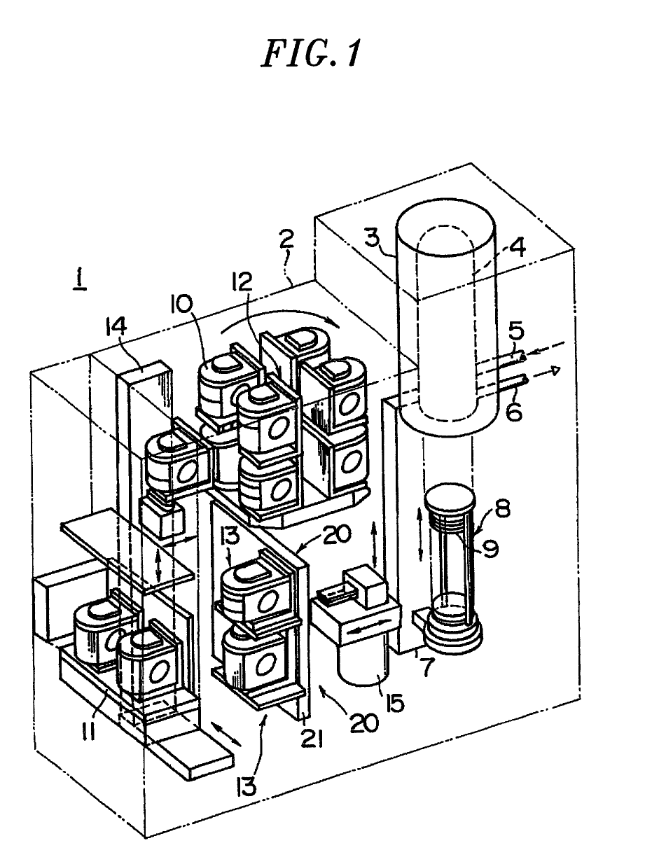

A substrate processing apparatus is a batch-type CVD apparatus 1 as shown in FIG. 1 for performing, e.g., a diffusion or a CVD process. The batch-type CVD apparatus 1 is provided with an airtightly sealed housing 2. At an upper portion of the rear side of the housing 2, a heater unit 3 is vertically installed and a process tube 4 is concentrically disposed within the heater unit 3. The process tube 4 has a gas supply line 5 for supplying a process gas or a purge gas into the process tube 4 and an exhaust line 6 for use in evacuating the process tube 4. At the lower portion of the rear side of the housing 2, a boat elevator 7 is installed to move a boat 8 located right below the process tube 4up and down, thereby loading or unloading the boat 8 into or from the process tube 4. A plurality of wafers 9 can be horizontally loaded in the boat 8 in such a manner that the centers of the wafers are vertically aligned while maintaining a predetermined distance therebetween.

Formed on a front wall 2a of the housing 2 is a pod load/unload opening (not shown) through which pods 10 can be loaded into or unloaded from the housing 2. The pod load/unload opening can be opened and closed by a shutter (not shown). Behind the pod load/unload opening, a pod stage 11 is provided for receiving and aligning the pods.

At the upper central portion of the housing 2, a rotatable pod shelf 12 is arranged. The pod shelf 12 is capable of holding, e.g., eight pods 10. The pod shelf 12 has two vertically disposed swastika-shaped pod supporting plates, each being capable of horizontally holding, e.g., 4 pods simultaneously. The pod shelf 12 is uni-directionally rotatable in a horizontal plane on a pitch-by-pitch basis by a rotary actuator (not shown), e.g., a stepping motor.

Below the pod shelf 12 in the housing 2, a pair of loading ports 13 are vertically disposed. Each loading port 13 is provided with a pod opener 20. It should be noted that the maximum capacity of the pod shelf 12 can be sixteen even though the capacity thereof is exemplified as eight in FIG. 1.

In the housing 2, a pod handler 14 is disposed near the pod stage 11, the pod shelf 12 and the wafer loading port 13 so that the pod handler 14 can transfer pods 10 between the pod stage 11 and the pod shelf 12, between the pod stage 11 and the wafer loading ports 13 and between the pod shelf 12 and the wafer loading port 13. A wafer carry assembly 15 is disposed between the boat 8 and the wafer loading ports 13 to transfer wafers 9 therebetween.

Details of the pod opener 20 will now be described with reference to FIGS. 1 to 6B.

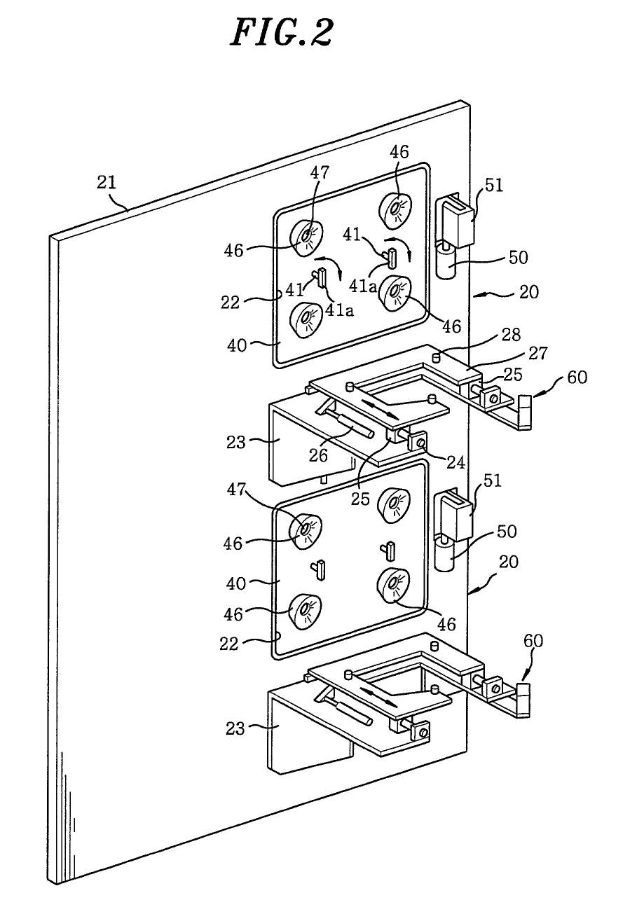

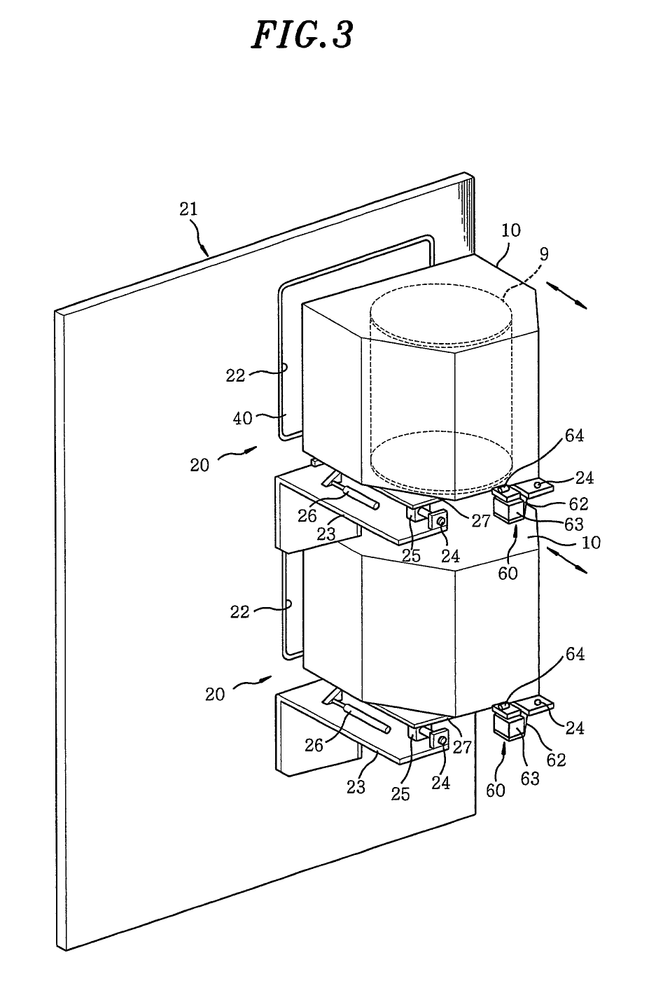

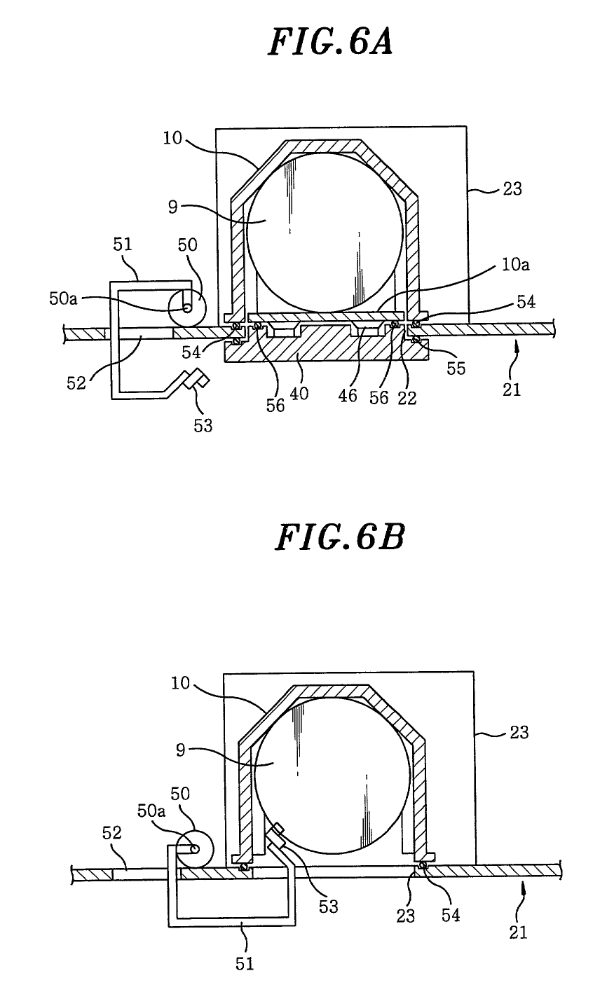

As shown in FIG. 1, there is provided a base 21 standing vertically between the wafer loading port 13 and the wafer carry assembly 15. The base 21 has two vertically disposed openings 22 formed therein and is shared by the two pod openers 20 as shown in FIGS. 2 and 3. The shape of each opening 22 is almost a rectangle similar to the cap 10a of the pod 10 but the size of the opening 22 is larger than that of the cap 10a as shown in FIGS. 6A and 6B.

As shown in FIG. 2, an angle shaped support 23 is horizontally provided below each opening 22 on a front surface of the base 21 and facing the pod stage 11. The support 23 is of a substantially square frame shape with a portion of a distal side thereof away from the base 21 removed, when viewed from top. A pair of guide rails 24 are mounted on the upper surface of each support 23, the guide rails 24 running parallel normal to the front surface of the base 21. A loading platform 27 is mounted on several guide blocks 25 slidably coupled with the guide rails 24. The loading platform 27 can move toward and away from the corresponding opening 22 by an air cylinder 26 mounted on the upper surface of the support 23.

The loading platform 27 also has a substantially square frame shape with a corner portion thereof away from the base 21 removed, when viewed from top. On the upper surface of the loading platform 27, vertically oriented alignment pins 28 are provided at locations corresponding to, e.g., three corners of an equilateral triangle. These pins are configured to be inserted into corresponding holes (not shown) formed at a bottom surface of a pod 10 when the pod 10 is mounted on the loading platform 27.

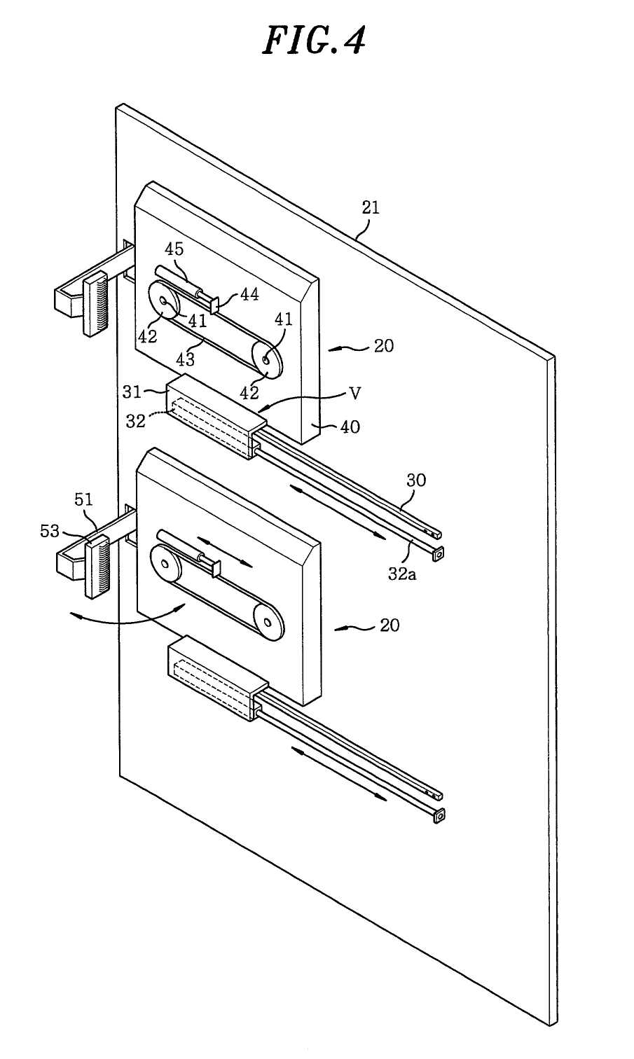

As shown in FIG. 4, a guide rail 30 is mounted on the rear surface of the base 21 below each opening 22, the rear surface facing the wafer carry assembly 15. The guide rail 30 is extended horizontally and runs parallel to the rear surface of the base 21. An angle-shaped slider 31 is slidably supported by the guide rail 30 and can reciprocate along the left- right direction. An air cylinder 32 is mounted on a vertical portion of the angle-shaped slider 31 parallel to the guide rail 30. An end portion of a piston rod 32a of the air cylinder 32 is anchored to the rear surface of the base 21. That is, the movement of the angle-shaped slider 31 is controlled by the retraction and extension of the air cylinder 32.

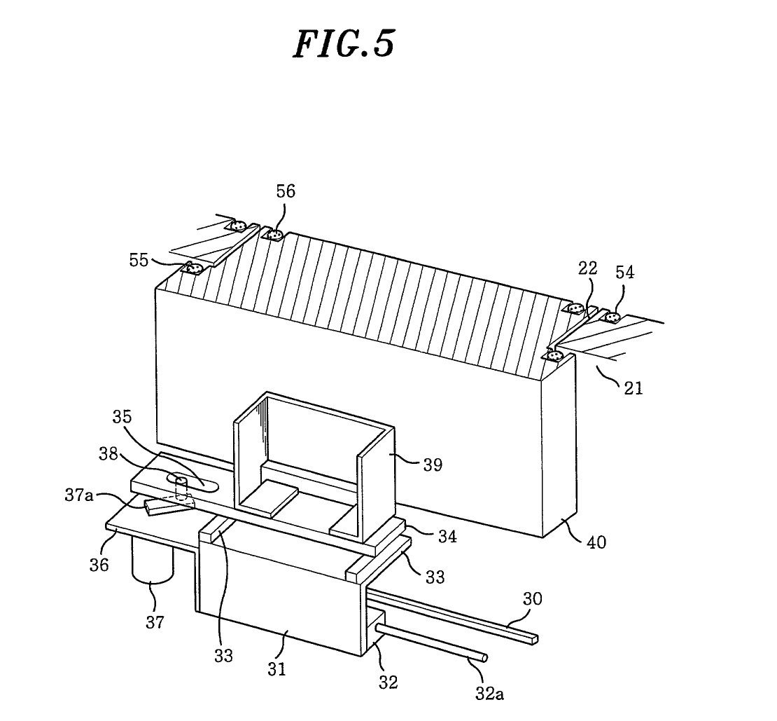

As shown in FIG. 5, a pair of parallel guide rails 33 running normal to the rear surface of the base 21 are installed on an upper surface of a horizontal portion of the angle-shaped slider 31. A back/forth slider 34 is slidably mounted on the guide rails 33 reciprocate back and forth. The back/forth slider 34 has a guide hole 35 extending in the left-right direction in one end portion, e.g., a left end portion of the back/forth slider 34. A bracket 36 is fixedly mounted on the left side of the angle-shaped slider 31 and a rotary actuator 37 is vertically mounted on the bracket 36. A guide pin 38 provided at an arm 37a of the rotary actuator 37 is slidably engaged with the guide hole 35. Therefore, the back/forth slider 34 is driven to move toward and away from the rear surface of the base 21 linearly by the rotating movement of the rotary actuator 37.

Mounted on the top surface of the back/forth slider 34 is a bracket 39. A closure 40, whose shape is similar to and whose size is a bit larger than the opening 22, is vertically fixed to the bracket 39. The square-shaped closure 40 is moved in a forward-backward direction by the back/forth slider 34 and in a left-right direction by the angle-shaped slider 31. The closure 40 is configured such that when the back/forth slider 34 is moved against the base 21, the peripheral front surface of the closure 40 can firmly contacts with the periphery of the opening 22 to thereby close the opening 22.

As shown in FIG. 4, a pair of keys 41 are rotatably inserted in corresponding holes symmetrically formed on the horizontal center line of the closure 40. Each key 41 is coupled with a pulley 42 provided at the end portion thereof on the rear surface of the closure 40. Both pulleys 42 are connected by a belt 43, which has a connection plate 44. An air cylinder 45 is horizontally located above one of the pulleys 42 and a piston rod thereof is connected to the connection plate 44 such that extension and retraction of the air cylinder 45 can produce a reciprocating rotary motion of the pulleys 42, thereby inducing the both keys 41 to rotate. In addition, as shown in FIG. 2, each key 41 includes a coupling member 41a at the end portion thereof emerging from the front surface of the closure 41 for engaging with a locking mechanism (not shown) on the cap 10a of the pod 10.

As shown in FIG. 2, four suction elements 46 capable of holding the cap 10a by vacuum suction are arranged on the front surface of each closure 40. Each suction element 46 is fixedly mounted by a suction pipe 47 serving as a screw having a male thread. The four suction elements 46 are respectively located at corresponding four points on the front surface of the closure 40 in such a manner that the center of a the rectangle formed by the four suction elements 46 substantially coincides with the center of the cap 10a. In addition, the four suction elements 47 can be disposed symmetric with respect to horizontal and vertical lines passing the center of the cap 10a. Each suction pipe 47 serving to fixedly hold the suction element 46 is a hollow tube or cylinder having a male thread at the outer surface thereof. An end of the suction pipe 47 exposed of the front surface of the closure 40 is arranged to be positioned below surface of the corresponding suction element 46 so that the end of the suction pipe 47 is not inserted into a corresponding alignment hole which can be provided in the cap 10a. That is, the suction pipe 47 of the preferred embodiment of the present invention does not function as a supporting pin for mechanically supporting a cap 10a. The other end of the suction pipe 47 at the back side of the closure 40 is connected to an air exhaust/supply pipe (not shown) inside of a cover 49 to be described later. It is to be appreciated that the four suction elements 46 may be disposed at corresponding four corners of a parallelogram, so that the suction elements 46 are symmetric with respect to the center of the cap 10a.

Referring to FIGS. 2, 4, 6A and 6B, a rotary actuator 50 having a vertically oriented rotary shaft 50a is installed on the front surface of the base 21 beside the opening 22. A C-shaped arm 51 is provided to pass through an opening 52 in the base 21. One end of the C-shaped arm 51 is connected to the rotary shaft 50a and a mapping device 53 for detecting the locations of wafers in the pod 10 is installed at the other end. The C-shaped arm 51 is rotated in one horizontal plane.

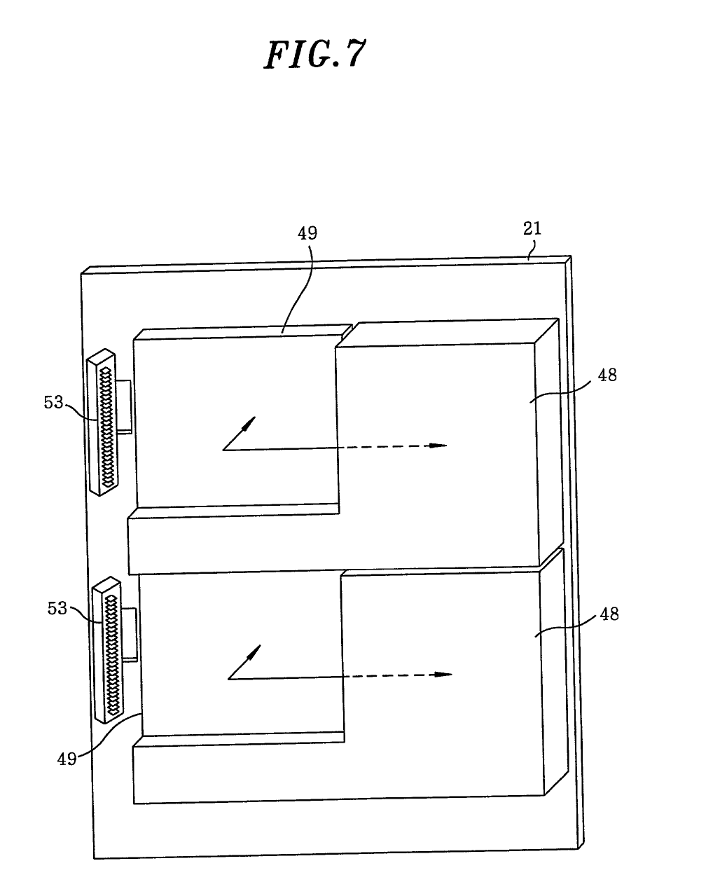

Further, as shown in FIG. 7, a first cover 48 is installed to cover the guide rail 30, the angle-shaped slider 31 and the air cylinder 32 and a second cover 49 to cover the parallel guide rail 33, the back/forth slider 34, the guide hole 35, the bracket 36, the rotary actuator 37, the guide pin 38, the bracket 39, the pulleys 42, the belt 43, the connecting plate 44 and the air cylinder 45. Further, as shown in FIGS. 5 and 6A, a packing member 55, e.g., an O-ring, may be provided around the peripheral front surface of the closure 40 in order to airtightly seal the opening 22 when the closure 40 shuts. Another packing member 56 may be provided on the peripheral region of the central front surface in order to seal a space formed between the cap 10a lodged on the wafer loading port 13 and the central front surface of the closure 40 when the closure 40 abuts the cap 10a. The packing member 56 serves to prevent contaminants on the cap 10a of the pod 10 from entering into the processing area where the wafer carry assembly 15 is located. An additional packing member 54 may also be provided on the front surface of the base 21 around each opening 22 in order for the front surface of the base 21 to airtightly contact with the cap frame of the pod 10.

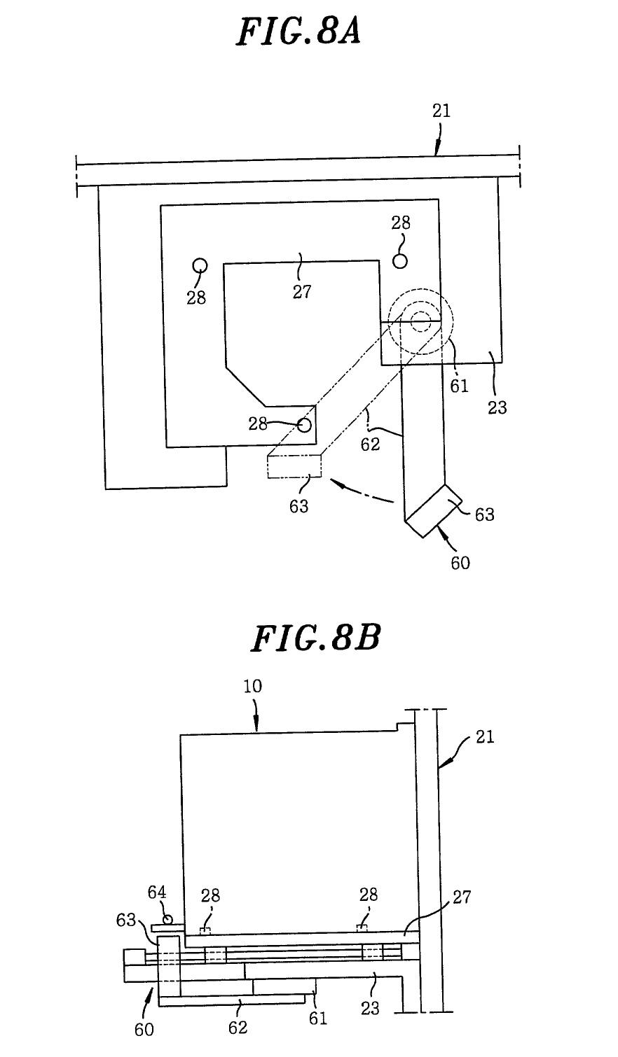

Further more, as shown in FIG. 8, a terminal unit 60 for reading and writing information about the wafers of the pod 10 is installed in the support 23 of the pod opener 20. The terminal unit 60 includes a rotary actuator 61 for reciprocatingly rotating an arm 62 between a parking position and an operation spot and a reading/writing (R/W) apparatus 63 vertically disposed at the free end of the arm 62. For example, the R/W apparatus 63 is a tag R/W apparatus capable of transferring information with a information storing device 64 by using an electromagnetic wave, wherein the information storing device 64 usually called a tag or an IC tag, i.e., a sort of IC memories, is disposed on lower part of the opposite side surface to the cap 10a. The R/W apparatus 63 is communicated with a controller (not shown) of the batch type CVD apparatus 1 and a host computer (not shown) integrally controlling the production process of semiconductor devices. For example, the tag 64 has a store of such information as lot numbers of the wafers 9 in the pods 10 or wafer identification codes, product numbers, history of processes undergone and recipes for processing conditions of the batch-type CVD apparatus 1. The practical processing condition of the batch-type CVD apparatus 1 or fault and error information regarding the batch-type CVD apparatus 1 operation are written in the tag 64.

The operation will now be described in accordance with the FIGS. 1 to 8.

As shown in FIG. 1, the pods 10 are loaded onto the pod stage 11 through the pod load/unload opening and then transferred by the pod handler 14 to predetermined positions on the pod shelf 12 for temporary storage.

Each pod 10 temporarily stored on the pod shelf 12 is transferred to the loading platform 27 of the pod opener 20 as shown in FIG. 3 and the pod 10 transferred thereto is aligned with the loading platform 27 for three alignment pins 28 of the loading platform 27 are inserted into the corresponding alignment holes of the pod 10.

Further, as shown in FIG. 8a, while the pod handler 14 is transferring the pod 10 to the loading platform 27, the R/W apparatus 63 of the terminal unit 60 is in its parking position lest the R/W apparatus 63 hinders transferring the pod 10 to the loading platform 27.

After the pod 10 transferred to the loading platform 27 is aligned therewith, the arm 62 is rotated by the rotary actuator 61 to be positioned at the operation spot as shown in FIG. 8A with a two-dot chain line. Accordingly, the R/W apparatus 63 vertically disposed at the free end of the arm 62 is located below the tag 64 of the pod 10 on the loading platform 27 to read information from the tag 64 by using an electromagnetic wave and then the R/W apparatus 63 sends the information to the controller of the batch-type CVD apparatus and the host computer.

The pod 10 aligned with the loading platform 27 is moved toward the base 21 by the extension of the air cylinder 26 in such a manner that the respective packing members 54 and 56 are airtightly in contact with the cap 10a and the pod frame therearound as shown in FIG. 6A. A pair of keys are inserted into the corresponding key holes of the cap 10a and the four suction elements 46 installed in the closure 40 adhere to the cap 10a and a negative pressure is applied in the suction pipe 47 through an air exhaust/supply pipe (not shown) so that the suction elements 46 hold the cap 10a by vacuum suction. Thereafter, the keys 41 inserted thereinto are rotated by the air cylinder 45 so that the coupling members 41a unlock the cap 10a.

Next, the back/forth slider 34 is moved away from the base 21 by the rotary actuator 37 and then the angle-shaped slider 31 is moved away from the opening 22 by the air cylinder 32 SO that the closure 40 and the cap 10a held thereby are moved to a retreated position (referring to arrows shown in FIG. 7). By such movement of the closure 40, the cap 10a is separated from the pod 10 and the pod 10 is opened as shown in FIG. 6B.

In opening process of the cap 10a by the closure 40, since holding force of the closure 40 is increased by installing the four suction elements 46 therein, the closure 40 can pull the cap 10a from the pod 10 certainly when moved backward from the base 21. In addition, as described above, since the center of the quadrangle formed by the four suction elements 46 coincides with the center of the closure 40 and the four suction elements 47 are symmetric with respect to the horizontal and vertical line passing the center of the closure 40, the cap 10a can maintain a vertical attitude without slanting and thereby can be transferred along the predetermined path to the retreated position.

Further, since the four suction elements 46 disposed on one vertical plane absorb the cap 10a, the vertical attitude of the cap 10a can be maintained. In other words, even though there is no pin, which is inserted into a corresponding hole in the cap 10a in order to maintain the vertical attitude of the cap 10a, the vertical attitude of the cap 10a can be maintained by the four suction elements 46.

After the wafer transferring opening of the pod 10 is opened, as shown in FIG. 6B, the C-shaped arm is rotated by the rotary actuator 50 so that the mapping device 53 is moved to the wafers 9 inside the pod 10 through the opening 22 and performs a mapping process by detecting the positions of the wafers 9, i.e., by identifying which slots the wafers 9 are disposed in. After the mapping process is completed, the mapping apparatus 53 is returned to its parking position by the rotary actuator 50.

Next, the wafers 9 in the pod 10 on the wafer loading port 13 are transferred to the wafer boat 8 by the wafer transfer assembly 15.

While the wafer transferring process is performed at the first, e.g., the upper wafer loading port 13, another pod 10 is transferred from the pod shelf 12 to the lower wafer loading port 13, aligned therewith and the opening process of the cap 10a and the mapping process are sequentially carried out.

Accordingly, upon the completion of the wafer transferring process of the first wafer loading port 13, another wafer transferring process can be started at the second wafer loading port 13. As a result, the wafer transferring operation can be continuously performed by the both wafer loading ports 13 without waiting time due to the replacement of the pods 10 and thus the system efficiency or the throughput of the batch-type CVD apparatus can be improved.

In the wafer transferring process from the pod 10 to the wafer boat 8, since the capacity of the wafer boat 8, e.g., 100 or 150, is several times greater than that of the pod 10, e.g., 25, a plurality of the pods 10 containing unprocessed wafers are alternately transferred to the both pod loading platforms 13.

After the predetermined number of unprocessed wafers are loaded on the wafer boat 8, the boat elevator 7 lifts the wafer boat 8 into the process tube 4. When the wafer boat 8 is completely introduced into the process tube 4, a lower end opening of the process tube 4 is hermetically sealed by the boat receptacle 8a.

Next, the process tube 4 is evacuated through the exhaust pipe 6 to reduce the pressure therein down to a predetermined vacuum level. Thereafter, in order to form a desired layer on the loaded wafers 9, a predetermined wafer process, e.g., a diffusion or a CVD process, is carried out by controlling temperature at desired levels by using the heater unit 3 while supplying predetermined process gases into the process tube 4 through the gas supply line 5.

After a predetermined period of processing time has elapsed, the wafer boat 8 holding processed wafers is discharged from the process tube 4 and returned to its initial position. In addition, during the period in which the wafer boat 8 is charged into and discharged from the process tube 4 and the wafers are processed in the process tube 4, one or two pods 10 are prepared at one or two corresponding wafer loading ports 13 in order to receive the processed wafers.

Thereafter, the wafer carry assembly 15 transfers a portion of the processed wafers held in the wafer boat 8 to one empty pod 10 previously transferred to, e.g., the first wafer loading port 13 (upper loading port) with the cap 10a opened.

Next, the cap 10a held by the closure 40 is moved toward the opening 22 by the angle-shaped slider 31 and shut into the wafer transferring opening of the pod 10 by the back/forth slider 34. While the cap 10a is returning to the pod 10, since four suction elements 46 hold the cap 10a, the cap 10a is safely returned to the pod 10 and fit well into the wafer transferring opening thereof.

After the cap 10a is fit into the wafer transferring opening of the pod 10, a pair of the keys are simultaneously rotated by the air cylinder 45 for the coupling member 41a to lock the cap 10a.

Next, a positive pressure is applied to four suction pipes 47 of the suction elements 46 through the air exhaust/supply pipe (not shown) so that four suction elements 46 release the cap 10a. The loading platform 27 is moved backward from the base 21 by the air cylinder 26. Accordingly, a pair of the keys 41 come out from the corresponding key holes of the cap 10a.

Next, the pods 10 containing the processed wafers are transferred to the pod shelf 12 by the pod handler 14 and temporarily stored therein.

In wafer transferring process from the boat 8 to the pods 10, since the capacity of the boat 8 is several times greater than that of the pod 10, a plurality of the pods 10 are transferred to the loading platforms 27 by the pod handler 14. In this case, while the processed wafers are transferred from the boat 8 to the pod 10 on one loading platform 27 by the wafer carry assembly 15, another pod 10 is prepared on the other loading platform 27 for receiving the processed wafers transferred by the wafer carry assembly 15. Accordingly, the wafer transferring process from the boat 8 to the pods 10 can be performed without waiting time and therefore, the throughput of the batch-type CVD apparatus 1 can be increased.

The pods 10 containing the processed wafers are temporarily stored in the pod shelf 12 and then transferred to the pod stage 11 by the pod handler 14. Next, the pods 10 on the pod stage 11 are transferred through the pod load/unload opening (not shown) to another equipment for a subsequent process and new pods containing unprocessed wafers are charged on the pod stage 11.

The processes of transferring pods 10 between the pod shelf 12 and the pod stage 11 and charging and discharging pods from the pod stage 11 can be carried out while the wafers 9 are being processed in the process tube 4 and being transferred between the wafer boat 8 and the pods 10 on the wafer loading ports 13. As a result, the total process time of the batch-type CVD apparatus 1 can be reduced.

Other wafers 9 are processed in the batch-type CVD 1 by performing the processes described above.

Following advantages can be achieved by the preferred embodiment of the present invention.

1) By installing four suction elements 46 in the closure 40 of the pod opener 20, which absorb the cap 10a, the holding force of the closure 40 is increased.

Accordingly, the closure 40 can pull and fit the cap 10a into the pod 10 certainly and transfer the cap 10a faster. As a result, the throughput of the batch-type CVD apparatus 1 can be improved.

2) By installing four suction elements 46 in such a manner that the center of the quadrangle formed by the four suction elements 46 coincides with the center of the cap 10a and that the four suction elements 46 are symmetric with respect to the horizontal and vertical line passing through the center of the closure 40, the cap 10a can maintain a vertical attitude without slanting and thereby can be transferred along the predetermined path between an initial position and the retreated position. Further, the same effect can be obtained by disposing the four suction elements 46 at corresponding corners of a parallelogram so that the suction elements 46 are symmetric with respect to the center of the cap 10a.

3) Since the cap 10a can be moved along the predetermined path while the cap is removed from the pod, fit in the pod 10 or transferred between the initial position and the retreated position, the cap 10 neither rubs against nor collides with other objects. Accordingly, undesired contaminants due to the rubbing or collision of the cap 10 with other objects is prevented. Further, unfitness of the cap in the pod, which prevents the cap from being closed and locked, is prevented.

4) Even though there is no pin, which is inserted into a corresponding hole in the cap 10a in order to maintain the vertical attitude of the cap 10a, the vertical attitude of the cap 10a can be maintained by the four suction elements 46. Accordingly, the conventional pin can be abolished from the closure 40.

5) By vertically installing a pair of the pod openers 20, each of which is capable of independently opening and restoring the cap 10a of the pod 10 on each wafer loading port 13, the wafer transferring process can be independently conducted at one wafer loading port 13 without waiting time while other pod 10 is prepared for the subsequent wafer transferring process at the other wafer loading port 13. As a result, the total process time can be considerably reduced and therefore the throughput of the batch-type CVD apparatus 1 can be increased.

6) By vertically arranging the wafer loading ports 13, the system efficiency can be improved without increasing the floor area or footprint of the batch-type CVD apparatus 1.

7) The vertically arranged loading ports 13 eliminates the need for the left-right movement of the wafer carry assembly 15 and thereby simplifies the structure thereof and improves the system efficiency without increasing the width of the batch-type CVD apparatus 1.

8) The independently operable mapping devices 53 provided to the respective wafer loading ports 13 enable the mapping process at one wafer loading port 13 and the wafer transferring process at the other to be conducted simultaneously. As a result, the subsequent wafer transferring process can be performed without waiting time and therefore, the total process time of the batch-type CVD apparatus 1 can be considerably reduced to increase the system efficiency.

9) By firmly attaching the arm 51 to the rotary shaft 51a installed on the front surface of the base 21 beside the opening 22 and disposing the mapping device 53 at the free end of the arm 51, the rotary actuating mechanism enables the mapping device 53 to approach and retreat from the wafers 9 in the pod 10 by the rotation of the rotary actuator. Accordingly, rotary actuating mechanism for the mapping device 53 can be simplified and small sized.

10) By installing the terminal unit 60 in the pod opener 20, the R/W apparatus 63 is capable of reading and writing on the tag 64 of the pod 10 disposed on the loading platform 27. Accordingly, the information about the necessary processing conditions in the batch-type CVD apparatus 1 can be obtained from the pod 10 and the result of the practical processing, e.g., the fault and error information regarding the batch type CVD apparatus 1 operation can be recorded on the tag 64 of the pod 10.

It is to be appreciated that the preferred embodiment of the present invention can be varied appropriately without departing from the scope of the present invention.

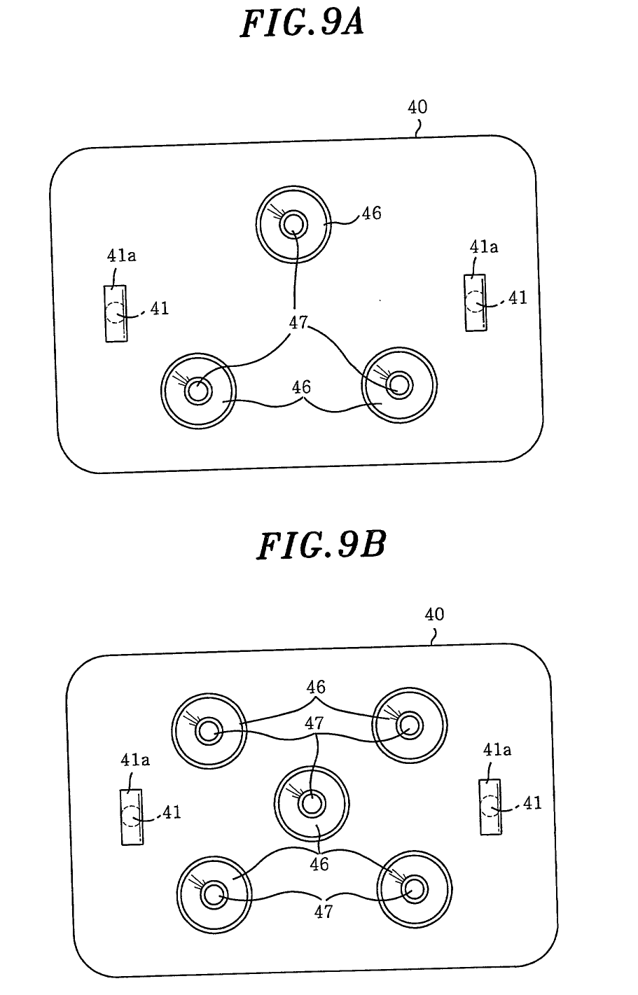

For example, as shown in FIG. 9, three or more suction elements 46 can be installed on the closure 40.

In FIG. 9a, there is shown a second preferred embodiment of the present invention having three suction elements 46. Three suction elements 46 are not disposed on a line but corresponding corners of a triangle. The center of the triangle substantially coincides with that of the cap 10a. Three suction elements 46 are symmetric with respect to the vertical line passing the center of the triangle. The closure 40 in accordance with the second preferred embodiment of the present invention can firmly absorb the cap 10a and certainly maintain the vertical attitude of the cap 10a like the closure 40 in accordance with the first preferred embodiment of the present invention.

Referring to FIG. 9b, there is shown a third preferred embodiment of the present invention having five suction elements 46. The suction elements 46 are disposed at corresponding corners of a quadrangle and the center thereof lest they are disposed in a line. The center of the quadrangle coincides with that of the cap 10a. Five suction elements are symmetric with respect to a vertical line passing the center of the quadrangle. The closure 40 in accordance with the second preferred embodiment of the present invention can firmly absorb the cap 10a and certainly maintain the vertical attitude of the cap 1a like the closure 40 in accordance with the first preferred embodiment of the present invention. It should be appreciated that the quadrangle can be a regular tetragon, a right-angled tetragon or a parallelogram.

It should be noted that more than two wafer loading ports can be installed vertically.

In addition, in lieu of the rotary actuator for actuating the mapping device, another mechanism using an X-Y axis robot can be employed. Moreover, the mapping device can be omitted if so required.

It should be appreciated that the mapping device can be an information reading device, e.g., a bar cord reader capable of reading bar cords in lieu of the device capable of reading and writing on the tag. In this case, the host computer forwards processing recipe to the batch-type CVD apparatus 1 depending on the information from the mapping device, wherein the information includes lot numbers or wafer identification codes.

Furthermore, it should be noted that the wafers can be replaced by photo masks, printed circuit boards, liquid crystal panels, compact disks and magnetic disks as a substrate.

The substrate processing apparatus can be of the type adapted to perform, e.g., oxide formation, diffusion process and other types of heat treating process in place of the CVD.

The present invention is also applicable to other types of substrate processing apparatus than the batch type-vertical CVD apparatus 1.

While the invention has been shown and described with respect to the preferred embodiments, it will be understood by those skilled in the art that various changes and modifications may be made without departing from the spirit and scope of the invention as defined in the following claims.

What is claimed is:

1. A substrate processing apparatus, comprising:
an opener including a closure, the opener for opening and restoring a cap of a wafer carrier,
wherein the closure has three or more suction elements for holding the cap of the wafer carrier.

2. The substrate processing apparatus of claim 1, wherein lines connecting centers of the suction elements form a polygon.

3. The substrate processing apparatus of claim 1, wherein a center of a largest polygon formed by lines connecting centers of the suction elements substantially coincides with a center of the cap.

4. The substrate processing apparatus of claim 2, wherein a center of a largest polygon formed by lines connecting the centers of the suction elements substantially coincides with a center of the cap.

5. The substrate processing apparatus of claim 1, wherein the suction elements are substantially symmetric with respect to a line passing through a center of the cap.

6. The substrate processing apparatus of claim 2, wherein the suction elements are substantially symmetric with respect to a line passing through a center of the cap.
